(19) United States
(12) Patent Application Publication
(10) Pub. No.: US 2023/0223283 A1
(43) Pub. Date: Jul. 13, 2023

(54) HEATING APPARATUS FOR A SEMICONDUCTOR DEVICE, HEATING SYSTEM, AND SEMICONDUCTOR DEVICE

(71) Applicant: ALIBABA GROUP HOLDING LIMITED, George Town (KY)

(72) Inventor: Chengchun TANG, Hangzhou (CN)

(21) Appl. No.: 18/147,227

(22) Filed: Dec. 28, 2022

(30) Foreign Application Priority Data
Jan. 11, 2022 (CN) 202210026973.7

(51) Int. Cl. H01L 21/67; G05D 23/27; H05B 1/02; H05B 3/74; F27B 17/00; F27D 7/06

(52) U.S. Cl. CPC H01L 21/67115; G05D 23/27; H05B 1/0233; H05B 3/744; F27B 17/0025; F27D 7/06; H01L 21/67248; H05B 2213/07; F27D 2007/066

(57) ABSTRACT

The present disclosure discloses a heating apparatus for a semiconductor device. The heating apparatus includes a carrier including a first abutting part, a heat collecting plate at least including a working surface, and a heat radiation source disposed on a side of the heat collecting plate opposite to the working surface and separated from the heat collecting plate by a predetermined distance. The heat collecting plate is disposed on the carrier, and the first abutting part abuts against an edge of the heat collecting plate on the side opposite to the working surface. The heat radiation source is and configured to emit heat radiation during working and to heat the heat collecting plate in a non-contact manner. The heat collecting plate receives the heat radiation and the emitted heat and heats a heated object disposed on the working surface in a contact manner.

### CROSS-REFERENCE TO RELATED APPLICATIONS

The present application claims priority to and the benefits of Chinese Patent Application Serial No. 202210026973.7, filed on Jan. 11, 2022, which is incorporated herein by reference in its entirety.

### TECHNICAL FIELD

The present disclosure relates to semiconductors, and specifically to a heating apparatus for a semiconductor device, a semiconductor vacuum heating system, and a semiconductor device.

### BACKGROUND

Semiconductor devices are the foundation of power electronic applications, and are also the core devices constituting power electronic change devices. They are mainly used for rectification, voltage stabilization, switching, frequency mixing, etc., of power electronic equipment, and have the characteristics of a wide range of applications and are heavily used.

In recent years, the call for the Internet of Everything (IoE) is increasing. Transportation vehicles represented by automobiles and high-speed railways, new energy fields represented by photovoltaics and wind power, communication devices represented by mobile phones, and consumer products represented by televisions, washing machines, air conditioners and refrigerators are all constantly improving the level of electronization, among which the high electronization of new-energy vehicles is the most eye-catching. At the same time, conventional industries such as industry and the power grid industry are also accelerating the electronization process.

However, in the existing technology, in a wafer manufacturing process, due to heat dissipation in other forms of energy, the temperature on the surface of the wafer is high at the center and low at the edges, which will cause adverse effects in the uniformity of the wafer. This problem is exacerbated in the case of the fabrication of large-size wafers.

Therefore, it has become an urgent problem to be solved to make the heating temperature on the surface of the wafer uniform and improve the fabrication yield of wafers for those skilled in the art.

### SUMMARY

Embodiments of the present disclosure provide a heating apparatus for a semiconductor device. The heating apparatus includes a carrier including a first abutting part, a heat collecting plate at least including a working surface, and a heat radiation source disposed on a side of the heat collecting plate opposite to the working surface and separated from the heat collecting plate by a predetermined distance. The heat collecting plate is disposed on the carrier, and the first abutting part abuts against an edge of the heat collecting plate on the side opposite to the working surface. The heat radiation source is and configured to emit heat radiation during working and to heat the heat collecting plate in a non-contact manner. The heat collecting plate receives the heat radiation and the emitted heat and heats a heated object disposed on the working surface in a contact manner.

Embodiments of the present disclosure further provide a semiconductor vacuum heating system. The semiconductor vacuum heating system includes a vacuum apparatus and a heating apparatus for a semiconductor device. The heating apparatus for the semiconductor device is disposed in a vacuum atmosphere of the vacuum apparatus. The heating apparatus includes a carrier including a first abutting part, a heat collecting plate at least including a working surface, and a heat radiation source disposed on a side of the heat collecting plate opposite to the working surface and separated from the heat collecting plate by a predetermined distance. The heat collecting plate is disposed on the carrier, and the first abutting part abuts against an edge of the heat collecting plate on the side opposite to the working surface. The heat radiation source is and configured to emit heat radiation during working and to heat the heat collecting plate in a non-contact manner. The heat collecting plate receives the heat radiation and the emitted heat and heats a heated object disposed on the working surface in a contact manner.

Embodiments of the present disclosure further provide a semiconductor device. The semiconductor device includes a semiconductor vacuum heating system. The semiconductor vacuum heating system includes a vacuum apparatus and a heating apparatus for a semiconductor device. The heating apparatus for the semiconductor device is disposed in a vacuum atmosphere of the vacuum apparatus. The heating apparatus includes a carrier including a first abutting part, a heat collecting plate at least including a working surface, and a heat radiation source disposed on a side of the heat collecting plate opposite to the working surface and separated from the heat collecting plate by a predetermined distance. The heat collecting plate is disposed on the carrier, and the first abutting part abuts against an edge of the heat collecting plate on the side opposite to the working surface. The heat radiation source is and configured to emit heat radiation during working and to heat the heat collecting plate in a non-contact manner. The heat collecting plate receives the heat radiation and the emitted heat and heats a heated object disposed on the working surface in a contact manner.

It should be understood that the above general descriptions and the following detailed descriptions are merely for exemplary and explanatory purposes, and do not limit the present disclosure.

### BRIEF DESCRIPTION OF THE DRAWINGS

To describe the technical solutions in the embodiments of the present disclosure or the prior art more clearly, the accompanying drawings required for describing the embodiments or the prior art are briefly introduced as follows. Apparently, the accompanying drawings described in the following are merely some embodiments in the present disclosure, and a person of ordinary skill in the art may still derive other drawings from these accompanying drawings without creative efforts.

FIG. 1 is a schematic structural diagram of an example heating apparatus for a semiconductor device according to some embodiments of the present disclosure.

FIG. 2 is another schematic structural diagram of an example heating apparatus for a semiconductor device according to some embodiments of the present disclosure.

FIG. 3 is a schematic structural diagram of an example heat collecting plate according to some embodiments of the present disclosure.

FIG. 4 is a schematic structural diagram of an example heat collecting plate in one direction according to some embodiments of the present disclosure.

FIG. 5 is a schematic structural diagram of an example contact structure according to some embodiments of the present disclosure.

FIG. 6 is a schematic structural diagram of another example contact structure according to some embodiments of the present disclosure.

FIG. 7 is yet another schematic structural diagram of an example heating apparatus for a semiconductor device according to some embodiments of the present disclosure.

### DETAILED DESCRIPTION

In the following description, numerous specific details are set forth in order to provide a thorough understanding of the present disclosure. However, the present disclosure can be implemented in many other ways that are different from those described herein, and those skilled in the art may make similar promotions without violating the connotation of the present disclosure. Therefore, the present disclosure is not limited by the specific implementations disclosed below.

Embodiments of the present disclosure provide a heating apparatus for a semiconductor device to solve the problem in the existing technology to make the heating temperature on the surface of a heated object uniform and to improve the fabrication yield of wafers. Embodiments of the present disclosure further provide a semiconductor vacuum heating system and a semiconductor device.

Compared with the existing technology, solutions provided in the present disclosure have the following advantages. In the embodiments of the present disclosure, a heat collecting plate is disposed on the carrier, and the heat collecting plate can uniformly receive heat radiation from the heat radiation source in a non-contact manner and transfer the heat received to the heated object in a contact manner, so that the heating temperature received by the heated object is relatively uniform, thus improving the fabrication yield of the heated object.

Some embodiments of the present disclosure provide a heating apparatus for a semiconductor device. Some other embodiments of the present disclosure provide a semiconductor vacuum heating system. Yet some other embodiments of the present disclosure provide a semiconductor device.

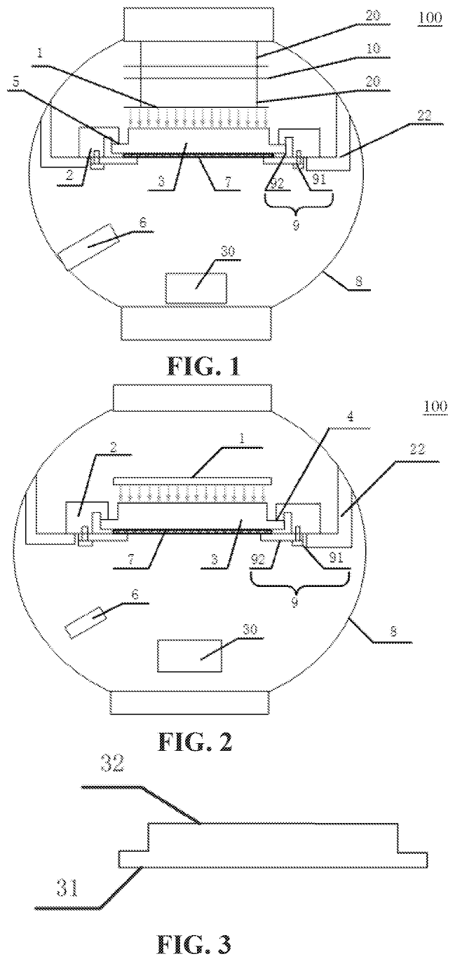

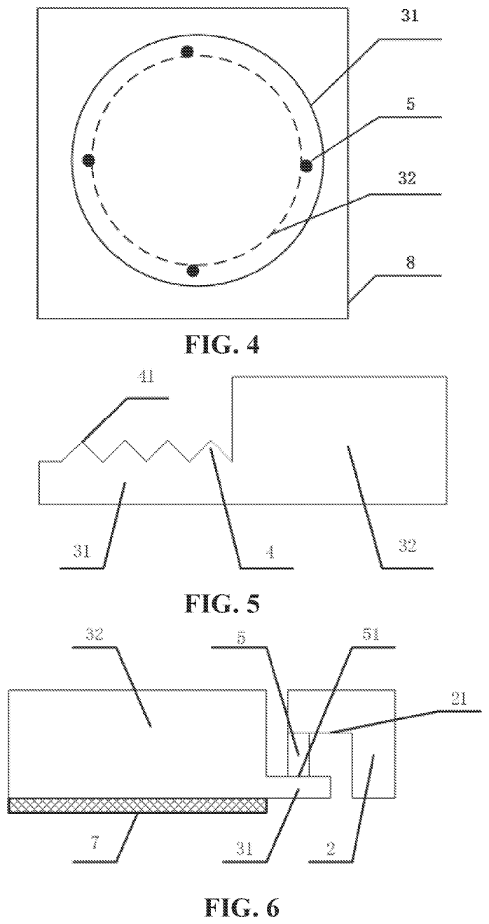

Reference is made to FIG. 1 to FIG. 6. FIG. 1 is a schematic structural diagram of an example heating apparatus for a semiconductor device according to some embodiments of the present disclosure. FIG. 2 is another schematic structural diagram of an example heating apparatus for a semiconductor device according to some embodiments of the present disclosure. FIG. 3 is a schematic structural diagram of an example heat collecting plate according to some embodiments of the present disclosure. FIG. 4 is a schematic structural diagram of an example heat collecting plate in one direction according to some embodiments of the present disclosure. FIG. 5 is a schematic structural diagram of an example contact structure according to some embodiments of the present disclosure. FIG. 6 is a schematic structural diagram of another example contact structure according to some embodiments of the present disclosure.

As shown in FIG. 1 to FIG. 6, a heating apparatus 100 for a semiconductor device according to some embodiments of the present disclosure includes a heat radiation source 1, a carrier 2, and a heat collecting plate 3. The aforementioned heating apparatus 100 may be disposed overall in a vacuum chamber 8. The heat radiation source 1 may be an infrared heat radiation source or other forms of heat radiation sources. The carrier 2 is disposed in the vacuum chamber 8 through a bracket 22. The carrier 2 at least includes a first abutting part 21. The heat collecting plate 3 is disposed on the carrier 2 through a fixing structure 9. The first abutting part 21 of the carrier 2 abuts against the edge of the heat collecting plate 3. The lower surface of the heat collecting plate 3 forms a working surface. The heat radiation source 1 is disposed on the side of the heat collecting plate 3 opposite to the working surface. That is, it is disposed above the heat collecting plate 3, and is separated from the heat collecting plate 3 by a predetermined distance. The heat radiation source 1 is configured to emit heat radiation during working and to heat the heat collecting plate 3 in a non-contact manner. The heat collecting plate 3 receives the heat radiation and the emitted heat and heats a heated object 7 disposed on the working surface in a contact manner.

In the embodiments of the present disclosure, the heat collecting plate 3 has a plate shape with a certain thickness. In some embodiments, the heat collecting plate 3 is configured to heat a semiconductor wafer, and the thickness of the heat collecting plate 3 is generally greater than the thickness of the heated object. The heat collecting plate 3 is heated by the heat radiation source 1, and after heated, the heat collecting plate 3 forms a heat source with uniform temperature, so that the semiconductor wafer on the working surface can be uniformly heated. In some embodiments, the heat collecting plate 3 can realize uniform heating of the wafer, which can eliminate or reduce the influence on the heated semiconductor wafer due to the temperature non-uniformity of the heat radiation source 1, and can also reduce the strict requirement on the temperature uniformity of the heat radiation source 1. In addition, by changing the distance between the heat collecting plate 3 and the heat radiation source 1, the temperature of the heat collecting plate 3 can be changed, to realize the heating of the semiconductor wafer under different temperature conditions, thus meeting the semiconductor wafer fabrication processes with different temperature requirements. Moreover, due to the high temperature uniformity of the heat collecting plate 3, the structure in the embodiments of the present disclosure can also achieve high temperature control precision.

The heating apparatus 100 of the embodiments of the present disclosure will be described in detail below with reference to specific examples. In some embodiments of the present disclosure, as shown in FIG. 4, the heat collecting plate 3 may have a circular shape, and include an integrally formed plate body 32 and an extension part extending outward along the radial direction of the lower surface (e.g., the working surface) of the plate body 32. This extension part forms a second abutting part 31 of the heat collecting plate 3. The heat collecting plate 3 is supported via the second abutting part 31 thereof on the first abutting part 21 of the carrier 2. The heat collecting plate 3 is only in contact with the first abutting part 21 of the carrier 2 via the second abutting part 31, and a certain gap exists between the remaining part and the carrier 2.

The heat radiation source 1 is disposed at a certain distance above the plate body 32, and the surface of the plate body 32 facing the heat radiation source 1 is provided as a rough surface to reduce the reflection of heat radiation, improve the ability to receive heat, and improve the utilization rate of heat energy. The working surface of the plate body 32 is provided as a smooth surface so that the working surface can be in sufficient contact with the heated object 7 (such as the wafer in the present embodiments), thus improving the efficiency of heat conduction and improving the uniformity of heating the heated object 7.

In some embodiments of the present disclosure, the heat collecting plate 3 is made of at least one of the following materials: zirconia, alumina, or silicon carbide, which can effectively improve the efficiency of heat conduction of the heat collecting plate 3.

In some embodiments of the present disclosure, the thickness of the second abutting part 31 of the heat collecting plate 3 is less than the thickness of the plate body 32, which is conducive to reducing the heat conduction between the heat collecting plate 3 and the carrier 2, reducing the heat loss, and reducing the influence of the carrier 2 on the temperature of the heat collecting plate 3, thus reducing the temperature variation effect at the edge of the heat collecting plate 3. In addition, the gap between the heat collecting plate 3 and the carrier 2 further reduces the heat conduction therebetween.

Further, in order to reduce the heat transfer between the heat collecting plate 3 and the carrier 2, a heat insulation structure may also be disposed between the second abutting part 31 of the heat collecting plate 3 and the first abutting part 21 of the carrier 2. This heat insulation structure may be fixed on the second abutting part 31 of the heat collecting plate 3 (e.g., be integrally formed with the second abutting part 31) or fixed on the first abutting part 21 of the carrier 2 (e.g., be integrally formed with the first abutting part 21). This heat insulation structure may be at least one of a heat-insulating column, a heat-insulating wedge structure, or a heat-insulating zigzag structure.

In some embodiments, the heat insulation structure may be the zigzag structure 4 as shown in FIG. 5, where this zigzag structure 4 may be disposed in the second abutting part 31 of the heat collecting plate 3 and integrally formed with the second abutting part 31 of the heat collecting plate 3. The tip 41 of the zigzag structure 4 faces the carrier 2 and the tip 41 of the heat-insulating zigzag structure 4 is in contact with the first abutting part 21 of the carrier 2. The heat-insulating zigzag structure 4 may also be disposed on the first abutting part 21 of the carrier 2 and integrally formed with the first abutting part 21 of the carrier 2, with the tip 41 of the zigzag structure 4 facing the second abutting part 31 of the heat collecting plate 3 and the tip 41 of the heat-insulating zigzag structure 4 being in contact with the plate surface of the second abutting part 31 of the heat collecting plate 3. With this zigzag structure 4, the contact area between the heat collecting plate 3 and the carrier 2 can be reduced, thereby reducing the heat conduction with the carrier 2, and further improving the uniformity of the temperature of the heat collecting plate 3 and improving the energy utilization efficiency.

In some other embodiments, the contact structure may also be a heat-insulating column 5 as shown in FIG. 6, such as a cylinder, a prism, a truncated-cone or a truncated-pyramid. The heat-insulating column 5 may be arranged to be integrally formed with the second abutting part 31 of the heat collecting plate 3, with the contact end 51 of the heat-insulating column 5 facing the carrier 2 and being in contact with the first abutting part 21 of the carrier 2. The heat-insulating column 5 may also be integrally formed with the first abutting part 21 of the carrier 2, with the contact end 51 of the heat-insulating column 5 facing the second abutting part 31 of the heat collecting plate 3 and being in contact with the second abutting part 31 of the heat collecting plate 3. It should be noted that, based on the material of the heat collecting plate 3, integrally forming the heat-insulating column 5 and the first abutting part 21 of the carrier 2 may reduce the difficulty of the manufacturing process.

The heat-insulating column 5, no matter whether being disposed on the second abutting part 31 of the heat collecting plate 3 or being disposed on the carrier 2, may be disposed at intervals along the circumferential direction of the heat collecting plate 3, and the number of the heat-insulating columns 5 disposed at intervals is at least 3. For example, the number of the heat-insulating columns 5 disposed at intervals can be set to 3, and the heat-insulating columns 5 can be evenly spaced based on the heat collecting plate 3 formed in the circular plate shape as a whole. In some other embodiments, the number of the heat-insulating columns 5 disposed at intervals may be set to 4, and as shown in FIG. 4, the heat-insulating columns 5 can be evenly spaced based on the heat collecting plate 3 formed in the circular plate shape as a whole.

Because the heat-insulating column 5 is disposed between the second abutting part 31 of the heat collecting plate 3 and the first abutting part 21 of the carrier 2, the contact area between the heat collecting plate 3 and the carrier 2 can be reduced, thereby reducing the heat conduction via the contact with the carrier 2, and further improving the uniformity of the temperature of the heat collecting plate 3 and improving the energy utilization efficiency.

In some other embodiments, the heat insulation structure disposed between the second abutting part 31 of the heat collecting plate 3 and the first abutting part 21 of the carrier 2 may also be in other structures, as long as the heat insulation structure can reduce the contact area between the heat collecting plate 3 and the carrier 2 when the heat collecting plate 3 is disposed on the carrier 2 so as to achieve the heat insulation effect, and such heat insulation structure is encompassed within the scope of the present disclosure.

In some embodiments of the present disclosure, in order to improve the stability of the arrangement of the heat collecting plate 3 on the carrier 2, the carrier 2 is also provided with a carrying structure adapted to the shape of the heat collecting plate 3. This carrying structure includes a concave stepped structure recessed from the end face of the carrier 2 and an accommodating hole penetrating the bottom surface of the concave stepped structure. The bottom surface of the concave stepped structure forms the first abutting part 21, and after the heat collecting plate 3 is disposed on the carrier 2, only the first abutting part 21 of the carrier 2 is in contact with the heat collecting plate 3. Specifically, in the mounted state, the second abutting part 31 of the heat collecting plate 3 is located in the concave stepped structure, and the plate body 32 of the heat collecting plate 3 is located in the accommodating hole.

In some embodiments of the present disclosure, in order to further reduce the heat loss of the heat collecting plate 3, when the heat collecting plate 3 is disposed on the carrier 2, a gap exists between the circumferential side of the second abutting part 31 of the heat collecting plate 3 and the side wall of the concave stepped structure. When the plate body 32 is accommodated in the accommodating hole, a gap exists between the side wall of the plate body 32 and the circumferential side wall of the accommodating hole.

In some embodiments of the present disclosure, in order to further reduce the heat loss when the heat radiation source 1 emits heat radiation, a radiation reflecting plate 10 is further disposed. As shown in FIG. 1, the radiation reflecting plate 10 is disposed on the side of the heat radiation source 1 opposite to the heat collecting plate 3 and is configured to reflect the heat radiation emitted by the heat radiation source 1 to the heat collecting plate 3. Specifically, the radiation reflecting plate 10 may be located directly above the heat radiation source 1, with one end face of the radiation reflecting plate 10 being connected to the vacuum chamber 8 through a connector 20, and the other end face of the radiation reflecting plate 10 being connected to the heat radiation source 1 through the connector 20. In some other embodiments, it is possible to provide the heat radiation source 1 without the radiation reflecting plate 10, as shown in FIG. 2.

In some embodiments of the present disclosure, the fixing structure 9 is disposed on the carrier 2, and the fixing structure 9 includes a fixing bolt 91 and a fixing clamp 92. One end of the fixing clamp 92 is fixed on the carrier 2 by the fixing bolt 91 and the other end of the fixing clamp 92 faces the working surface of the heat collecting plate 3, and a space for clamping the heated object 7 is provided between the fixing clamp 92 and the working surface of the heat collecting plate 3. After the heated object 7 is placed on the working surface of the heat collecting plate 3, it can be fixed by the fixing clamp 92 to avoid the heated object 7 falling off from the working surface.

In addition, as shown in FIG. 1, the heating apparatus in some embodiments may also be provided with a temperature measuring apparatus 6 and a temperature control apparatus (not shown). The temperature measuring apparatus 6 is disposed on the side of the working surface of the heat collecting plate 3 or on the bracket 22 of the vacuum chamber 8. The temperature measuring apparatus 6 is separated from the heat collecting plate 3 by a set distance, and is configured to measure the real-time temperature of the heated object 7 being heated on the heat collecting plate 3. The temperature control apparatus is connected to the temperature measuring apparatus 6 and the heat radiation source 1 and is configured to adjust the temperature of the heat radiation source 1 according to the temperature of the heated object 7 measured by the temperature measuring apparatus 6, so that the heat radiation source 1 can adjust the output of heat in time. For example, the heat radiation source 1 may set a standard temperature for heating the heated object 7, and if the temperature value of the real-time temperature obtained by the temperature measuring apparatus 6 and the temperature control apparatus is lower than the standard temperature, the heat radiation source 1 is configured to heat, or compensate for the heat loss of, the heated object 7. Here, the temperature measuring apparatus 6 includes an infrared temperature sensor. In addition, in some embodiments of the present disclosure, the vacuum chamber 8 is also provided with a hot crucible, an electron gun, a magnetron target, an evaporation source 30, and the like.

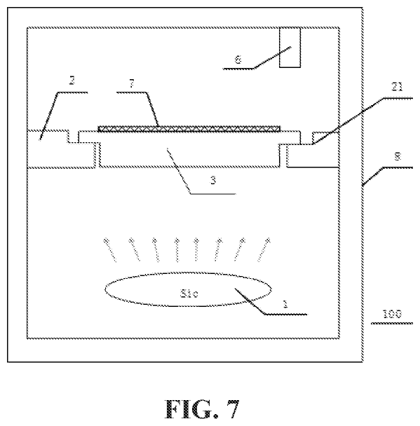

In some other embodiments of the present disclosure, the heating apparatus 100 for a semiconductor device can also be provided as the structure shown in FIG. 7. FIG. 7 is yet another schematic structural diagram of an example heating apparatus 100 for a semiconductor device according to some embodiments of the present disclosure. The heating apparatus 100 includes a heat radiation source 1, a carrier 2, and a heat collecting plate 3. The aforementioned heating apparatus 100 may be, as a whole, disposed in the vacuum chamber 8. The heat radiation source 1 may be an infrared heat radiation source or other forms of heat radiation sources. The carrier 2 is disposed in the vacuum chamber 8 through the bracket 22. The carrier 2 at least includes the first abutting part 21. The heat collecting plate 3 is disposed on the carrier 2. The bottom edge of the heat collecting plate 3 is supported by the first abutting part 21 of the carrier 2, and the upper surface of the heat collecting plate 3 forms the working surface. The heat radiation source is disposed on the side of the heat collecting plate 3 opposite to the working surface. That is, it is disposed under the heat collecting plate 3, and is separated from the heat collecting plate 3 by a predetermined distance. The heat radiation source 1 is configured to emit heat radiation during working and to heat the heat collecting plate 3 in a non-contact manner. The heat collecting plate 3 receives the heat radiation and the emitted heat and heats the heated object 7 disposed on the working surface in a contact manner.

Other descriptions regarding the structure of the heating apparatus 100 of the embodiments of FIG. 7 may be found in the embodiments of the present disclosure described above, and thus are not repeated herein for the sake of brevity. The temperature uniformity of heating of the heated object 7 can be achieved no matter the heat radiation source 1 is arranged above or below the heat collecting plate 3.

The heating apparatus 100 for a semiconductor device according to various embodiments of the present disclosure can improve the temperature uniformity of heating of the heated object 7, and further improve the fabrication yield of the heated object 7. Further, the heating apparatus 100 has a simple structure, which is conducive to reducing the manufacturing cost.

In addition, the present disclosure further provides a semiconductor vacuum heating system (not shown) including a vacuum apparatus and the heating apparatus for a semiconductor device of the above embodiments. The vacuum apparatus includes the vacuum chamber 8 as shown in FIG. 1. The heating apparatus for the semiconductor device is disposed in the vacuum chamber 8 of the vacuum apparatus. The heating apparatus based on the aforementioned semiconductor device has been described in detail in the above embodiments, and thus those descriptions are not repeated herein.

In addition, the present disclosure further provides a semiconductor device including the semiconductor vacuum heating system provide by the embodiments of the present disclosure.

The embodiments may further be described using the following clauses:
1. A heating apparatus for a semiconductor device, comprising:
a carrier comprising a first abutting part;
a heat collecting plate comprising a working surface, wherein the heat collecting plate is disposed on the carrier, and the first abutting part abuts against an edge of the heat collecting plate on a side opposite to the working surface; and
a heat radiation source disposed on the side of the heat collecting plate opposite to the working surface and separated from the heat collecting plate by a predetermined distance, and configured to emit heat radiation during working and to heat the heat collecting plate in a non-contact manner, wherein the heat collecting plate receives the heat radiation and emitted heat and heats a heated object disposed on the working surface in a contact manner.
2. The heating apparatus for the semiconductor device of clause 1, wherein the heat collecting plate further comprises a second abutting part at the edge of the heat collecting plate on the side opposite to the working surface, and a thickness of the second abutting part is smaller than a thickness of remaining parts of the heat collecting plate;
wherein the second abutting part of the heat collecting plate is supported on the first abutting part of the carrier.
3. The heating apparatus for the semiconductor device of clause 2, wherein a heat insulation structure is further arranged between the first abutting part of the carrier and the second abutting part of the heat collecting plate.
4. The heating apparatus for the semiconductor device of clause 3, wherein the heat insulation structure comprises at least one of a heat-insulating column, a heat-insulating wedge structure, or a heat-insulating zigzag structure.
5. The heating apparatus for the semiconductor device of clause 4, wherein the heat insulation structure is integrally formed with the first abutting part, or the heat insulation structure is integrally formed with the second abutting part.
6. The heating apparatus for the semiconductor device of clause 4 or clause 5, wherein the heat collecting plate has a circular shape, and the heat insulation structure comprises at least three heat-insulating columns distributed along a circumferential direction of the heat collecting plate.
7. The heating apparatus for the semiconductor device of clause 6, wherein the heat-insulating columns are cylindrical, prismatic, truncated-cone shaped, or truncated-pyramid shaped.
8. The heating apparatus for the semiconductor device of any of clauses 1-5, wherein the carrier is provided with a carrying structure adapted to a shape of the heat collecting plate, the carrying structure comprises a concave stepped structure, a bottom surface of the concave stepped structure forming the first abutting part;
wherein after the heat collecting plate is disposed on the carrier, only the first abutting part of the carrier is in contact with the heat collecting plate.
9. The heating apparatus for the semiconductor device of any of clauses 1-5, further comprising:
a radiation reflecting plate disposed on the side of the heat radiation source opposite to the heat collecting plate and configured to reflect the heat radiation emitted by the heat radiation source to the heat collecting plate.
10. The heating apparatus for the semiconductor device of any of clauses 1-5, further comprising:
a temperature measuring apparatus disposed on the side of the working surface of the heat collecting plate and separated from the heat collecting plate by a set distance, and configured to measure the temperature of the heated object; and
a temperature control apparatus connected to the temperature measuring apparatus and the heat radiation source, and is configured to adjust the temperature of the heat radiation source according to the temperature of the heated object measured by the temperature measuring apparatus.
11. A semiconductor vacuum heating system, comprising:
a vacuum apparatus; and
a heating apparatus for a semiconductor device disposed in a vacuum atmosphere of the vacuum apparatus, the heating apparatus comprising:
a carrier comprising a first abutting part;
a heat collecting plate comprising a working surface, wherein the heat collecting plate is disposed on the carrier, and the first abutting part abuts against an edge of the heat collecting plate on a side opposite to the working surface; and
a heat radiation source disposed on the side of the heat collecting plate opposite to the working surface and separated from the heat collecting plate by a predetermined distance, and configured to emit heat radiation during working and to heat the heat collecting plate in a non-contact manner, wherein the heat collecting plate receives the heat radiation and emitted heat and heats a heated object disposed on the working surface in a contact manner.
12. The semiconductor vacuum heating system of clause 11, wherein the heat collecting plate further comprises a second abutting part at the edge of the heat collecting plate on the side opposite to the working surface, and a thickness of the second abutting part is smaller than a thickness of remaining parts of the heat collecting plate;
wherein the second abutting part of the heat collecting plate is supported on the first abutting part of the carrier.
13. The semiconductor vacuum heating system of clause 12, wherein a heat insulation structure is further arranged between the first abutting part of the carrier and the second abutting part of the heat collecting plate.
14. The semiconductor vacuum heating system of clause 13, wherein the heat insulation structure comprises at least one of a heat-insulating column, a heat-insulating wedge structure, or a heat-insulating zigzag structure.
15. The semiconductor vacuum heating system of clause 14, wherein the heat insulation structure is integrally formed with the first abutting part, or the heat insulation structure is integrally formed with the second abutting part.
16. The semiconductor vacuum heating system of clause 14 or clause 15, wherein the heat collecting plate has a circular shape, and the heat insulation structure comprises at least three heat-insulating columns distributed along a circumferential direction of the heat collecting plate.
17. The semiconductor vacuum heating system of clause 16, wherein the heat-insulating columns are cylindrical, prismatic, truncated-cone shaped, or truncated-pyramid shaped.
18. The semiconductor vacuum heating system of any of clauses 11-15, wherein the carrier is provided with a carrying structure adapted to a shape of the heat collecting plate, the carrying structure comprises a concave stepped structure, a bottom surface of the concave stepped structure forming the first abutting part;
wherein after the heat collecting plate is disposed on the carrier, only the first abutting part of the carrier is in contact with the heat collecting plate.
19. The semiconductor vacuum heating system of any of clauses 11-15, wherein the heating apparatus further comprises:
a radiation reflecting plate disposed on the side of the heat radiation source opposite to the heat collecting plate and configured to reflect the heat radiation emitted by the heat radiation source to the heat collecting plate.
20. The semiconductor vacuum heating system of any of clauses 11-15, wherein the heating apparatus further comprises:
a temperature measuring apparatus disposed on the side of the working surface of the heat collecting plate and separated from the heat collecting plate by a set distance, and configured to measure the temperature of the heated object; and
a temperature control apparatus connected to the temperature measuring apparatus and the heat radiation source, and is configured to adjust the temperature of the heat radiation source according to the temperature of the heated object measured by the temperature measuring apparatus.
21. A semiconductor device, comprising:
a semiconductor vacuum heating system, comprising:
a vacuum apparatus; and
a heating apparatus for the semiconductor device disposed in a vacuum atmosphere of the vacuum apparatus, the heating apparatus comprising:
a carrier comprising a first abutting part;
a heat collecting plate comprising a working surface, wherein the heat collecting plate is disposed on the carrier, and the first abutting part abuts against an edge of the heat collecting plate on a side opposite to the working surface; and
a heat radiation source disposed on the side of the heat collecting plate opposite to the working surface and separated from the heat collecting plate by a predetermined distance, and configured to emit heat radiation during working and to heat the heat collecting plate in a non-contact manner, wherein the heat collecting plate receives the heat radiation and emitted heat and heats a heated object disposed on the working surface in a contact manner.
22. The semiconductor device of clause 21, wherein the heat collecting plate further comprises a second abutting part at the edge of the heat collecting plate on the side opposite to the working surface, and a thickness of the second abutting part is smaller than a thickness of remaining parts of the heat collecting plate;
wherein the second abutting part of the heat collecting plate is supported on the first abutting part of the carrier.
23. The semiconductor device of clause 22, wherein a heat insulation structure is further arranged between the first abutting part of the carrier and the second abutting part of the heat collecting plate.
24. The semiconductor device of clause 23, wherein the heat insulation structure comprises at least one of a heat-insulating column, a heat-insulating wedge structure, or a heat-insulating zigzag structure.
25. The semiconductor device of clause 24, wherein the heat insulation structure is integrally formed with the first abutting part, or the heat insulation structure is integrally formed with the second abutting part.
26. The semiconductor device of clause 24 or clause 25, wherein the heat collecting plate has a circular shape, and the heat insulation structure comprises at least three heat-insulating columns distributed along a circumferential direction of the heat collecting plate.
27. The semiconductor device of clause 26, wherein the heat-insulating columns are cylindrical, prismatic, truncated-cone shaped, or truncated-pyramid shaped.
28. The semiconductor device of any of clauses 21-25, wherein the carrier is provided with a carrying structure adapted to a shape of the heat collecting plate, the carrying structure comprises a concave stepped structure, a bottom surface of the concave stepped structure forming the first abutting part;
wherein after the heat collecting plate is disposed on the carrier, only the first abutting part of the carrier is in contact with the heat collecting plate.
29. The semiconductor device of any of clauses 21-25, wherein the heating apparatus further comprises:
a radiation reflecting plate disposed on the side of the heat radiation source opposite to the heat collecting plate and configured to reflect the heat radiation emitted by the heat radiation source to the heat collecting plate.
30. The semiconductor device of any of clauses 21-25, wherein the heating apparatus further comprises:
a temperature measuring apparatus disposed on the side of the working surface of the heat collecting plate and separated from the heat collecting plate by a set distance, and configured to measure the temperature of the heated object; and
a temperature control apparatus connected to the temperature measuring apparatus and the heat radiation source, and is configured to adjust the temperature of the heat radiation source according to the temperature of the heated object measured by the temperature measuring apparatus.

Although the present disclosure has been disclosed using various embodiments, it is not intended to limit the present disclosure. Any person skilled in the art can make possible changes and modifications without departing from the spirit and scope of the present disclosure. Therefore, the scope of protection of the present disclosure should be based on the scope defined in the claims of the present disclosure.

1. A heating apparatus for a semiconductor device, comprising:
a carrier comprising a first abutting part;
a heat collecting plate comprising a working surface, wherein the heat collecting plate is disposed on the carrier, and the first abutting part abuts against an edge of the heat collecting plate on a side opposite to the working surface; and
a heat radiation source disposed on the side of the heat collecting plate opposite to the working surface and separated from the heat collecting plate by a predetermined distance, and configured to emit heat radiation during working and to heat the heat collecting plate in a non-contact manner, wherein the heat collecting plate receives the heat radiation and emitted heat and heats a heated object disposed on the working surface in a contact manner.

2. The heating apparatus for the semiconductor device of claim 1, wherein the heat collecting plate further comprises a second abutting part at the edge of the heat collecting plate on the side opposite to the working surface, and a thickness of the second abutting part is smaller than a thickness of remaining parts of the heat collecting plate;
wherein the second abutting part of the heat collecting plate is supported on the first abutting part of the carrier.

3. The heating apparatus for the semiconductor device of claim 2, wherein a heat insulation structure is further arranged between the first abutting part of the carrier and the second abutting part of the heat collecting plate.

4. The heating apparatus for the semiconductor device of claim 3, wherein the heat insulation structure comprises at least one of a heat-insulating column, a heat-insulating wedge structure, or a heat-insulating zigzag structure.

5. The heating apparatus for the semiconductor device of claim 4, wherein the heat insulation structure is integrally formed with the first abutting part, or the heat insulation structure is integrally formed with the second abutting part.

6. The heating apparatus for the semiconductor device of claim 4, wherein the heat collecting plate has a circular shape, and the heat insulation structure comprises at least three heat-insulating columns distributed along a circumferential direction of the heat collecting plate.

7. The heating apparatus for the semiconductor device of claim 6, wherein the heat-insulating columns are cylindrical, prismatic, truncated-cone shaped, or truncated-pyramid shaped.

8. The heating apparatus for the semiconductor device of claim 1, wherein the carrier is provided with a carrying structure adapted to a shape of the heat collecting plate, the carrying structure comprises a concave stepped structure, a bottom surface of the concave stepped structure forming the first abutting part;
wherein after the heat collecting plate is disposed on the carrier, only the first abutting part of the carrier is in contact with the heat collecting plate.

9. The heating apparatus for the semiconductor device of claim 1, further comprising:
a radiation reflecting plate disposed on the side of the heat radiation source opposite to the heat collecting plate and configured to reflect the heat radiation emitted by the heat radiation source to the heat collecting plate.

10. The heating apparatus for the semiconductor device of claim 1, further comprising:
a temperature measuring apparatus disposed on the side of the working surface of the heat collecting plate and separated from the heat collecting plate by a set distance, and configured to measure the temperature of the heated object; and
a temperature control apparatus connected to the temperature measuring apparatus and the heat radiation source, and is configured to adjust the temperature of the heat radiation source according to the temperature of the heated object measured by the temperature measuring apparatus.

11. A semiconductor vacuum heating system, comprising:
a vacuum apparatus; and
a heating apparatus for a semiconductor device disposed in a vacuum atmosphere of the vacuum apparatus, the heating apparatus comprising:
a carrier comprising a first abutting part;
a heat collecting plate comprising a working surface, wherein the heat collecting plate is disposed on the carrier, and the first abutting part abuts against an edge of the heat collecting plate on a side opposite to the working surface; and
a heat radiation source disposed on the side of the heat collecting plate opposite to the working surface and separated from the heat collecting plate by a predetermined distance, and configured to emit heat radiation during working and to heat the heat collecting plate in a non-contact manner, wherein the heat collecting plate receives the heat radiation and emitted heat and heats a heated object disposed on the working surface in a contact manner.

12. The semiconductor vacuum heating system of claim 11, wherein the heat collecting plate further comprises a second abutting part at the edge of the heat collecting plate on the side opposite to the working surface, and a thickness of the second abutting part is smaller than a thickness of remaining parts of the heat collecting plate;
wherein the second abutting part of the heat collecting plate is supported on the first abutting part of the carrier.

13. The semiconductor vacuum heating system of claim 12, wherein a heat insulation structure is further arranged between the first abutting part of the carrier and the second abutting part of the heat collecting plate.

14. The semiconductor vacuum heating system of claim 13, wherein the heat insulation structure comprises at least one of a heat-insulating column, a heat-insulating wedge structure, or a heat-insulating zigzag structure.

15. The semiconductor vacuum heating system of claim 14, wherein the heat insulation structure is integrally formed with the first abutting part, or the heat insulation structure is integrally formed with the second abutting part.

16. The semiconductor vacuum heating system of claim 14, wherein the heat collecting plate has a circular shape, and the heat insulation structure comprises at least three heat-insulating columns distributed along a circumferential direction of the heat collecting plate.

17. The semiconductor vacuum heating system of claim 16, wherein the heat-insulating columns are cylindrical, prismatic, truncated-cone shaped, or truncated-pyramid shaped.

18. The semiconductor vacuum heating system of claim 11, wherein the carrier is provided with a carrying structure adapted to a shape of the heat collecting plate, the carrying structure comprises a concave stepped structure, a bottom surface of the concave stepped structure forming the first abutting part;
wherein after the heat collecting plate is disposed on the carrier, only the first abutting part of the carrier is in contact with the heat collecting plate.

19. The semiconductor vacuum heating system of claim 11, wherein the heating apparatus further comprises:
a radiation reflecting plate disposed on the side of the heat radiation source opposite to the heat collecting plate and configured to reflect the heat radiation emitted by the heat radiation source to the heat collecting plate.

20. A semiconductor device, comprising:
a semiconductor vacuum heating system, comprising:
a vacuum apparatus; and
a heating apparatus for the semiconductor device disposed in a vacuum atmosphere of the vacuum apparatus, the heating apparatus comprising:
a carrier comprising a first abutting part;
a heat collecting plate comprising a working surface, wherein the heat collecting plate is disposed on the carrier, and the first abutting part abuts against an edge of the heat collecting plate on a side opposite to the working surface; and
a heat radiation source disposed on the side of the heat collecting plate opposite to the working surface and separated from the heat collecting plate by a predetermined distance, and configured to emit heat radiation during working and to heat the heat collecting plate in a non-contact manner, wherein the heat collecting plate receives the heat radiation and emitted heat and heats a heated object disposed on the working surface in a contact manner.
